(19) United States
(12) Patent Application Publication
(10) Pub. No.: US 2004/0153917 A1
(43) Pub. Date: Aug. 5, 2004

(54) Method for detecting defectives in an integrated circuit

(76) Inventors: Janne-wha Wu, Chiai (TW); Cheng-chi Hu, Tainan (TW); Ying-chou Shih, Tainan (TW); Chung-er Huang, Taipei (TW)

Correspondence Address: MARTINE & PENILLA, LLP, 710 LAKEWAY DRIVE, SUITE 170, SUNNYVALE, CA, 94085, US

(21) Appl. No.: 10/383,190

(22) Filed: Mar. 5, 2003

(30) Foreign Application Priority Data
Dec. 20, 2002 (TW) 91137004

(51) Int. Cl. G01R 31/28

(52) U.S. Cl. 714/724

(57) ABSTRACT

The invention discloses a method for detecting defectives in an integrated circuit. The integrated circuit is composed of a plurality of transistors in parallel on a wafer. The method includes the following two steps: applying a bias to the transistors, and extracting the infrared images of the transistors.

### BACKGROUND OF THE INVENTION

1. Field of the Invention

The invention relates to a method for detecting defectives in an integrated circuit and, more particularly, to a method for detecting defectives in an integrated circuit composed of transistors during the wafer level and the packaging level in semiconductor fabrication by utilizing the heat sensing principle of infrared light.

2. Description of the Related Art

One of the key electronic components of a handset is the radio frequency power amplifier (RFPA). Usually, the RFPA is configured by several tens of transistors in parallel to form a large transistor cell array for enhancing its output power. At present, an integrated circuit (IC) with such large transistor cell array often utilizes methods of visual in-line inspection and direct-current (DC) electrical probing test to perform testing during the wafer level and the packaging level in semiconductor fabrication in order to find defectives. However, the above-mentioned two methods have their shortcomings when applied to real-life implementations. With regard to the visual in-line inspection, since the inspection can only find structural defects and the inspecting speed is slow, the visual in-line inspection is not suitable for inspecting the large size device of the whole wafer. On the other hand, with regard to the DC electrical probing test, since the probe cannot distinguish the drift of DC amplification from an ineffective electronic component (such as a transistor) or an open circuit under the circumstance that an integrated circuit is composed of many electronic components in parallel, such as the RFPA being composed of transistors, the DC electrical probing test often misjudges the situation as normal. Although the result of misjudging will not totally damage the integrated circuit in the short term, it will diminish the lifespan of the device in the long term; consequently, the reliability of the device will decline. Hence, using the above-mentioned visual in-line inspection and DC electrical probing test cannot detect defectives effectively and completely.

In viewing the above problem, the invention provides a method for detecting defectives in an integrated circuit in order to effectively detect the earlier impaired electronic components during the wafer level and the packaging level.

### SUMMARY OF THE INVENTION

To solve the above-mentioned problem, the first object of the invention is to provide a method for detecting defectives in an integrated circuit in order to screen out the defectives during the wafer level and the packaging level.

The second object of the invention is to provide a method for detecting defectives in an integrated circuit, which can be performed on an auto-probing platform in order to screen out the defectives during the wafer level and packaging level.

The third object of the invention is to provide a method for detecting defectives in an integrated circuit, which can detect the defective transistors in the RFPA circuits and debug the circuit design for the RFPA circuits.

According to an aspect of the invention, the method for detecting defectives in an integrated circuit that is composed of a plurality of transistors in parallel on a wafer includes the following two steps: applying a bias to the transistors in parallel, and extracting the infrared images of the transistors.

In the first embodiment of the invention, before the bias is applied to the transistors, the wafer is placed on an auto-probing platform equipped with a probe clamp that is used for holding at least one probe, and at least one probe is used for conducting in direct current from the power supply so as to apply the bias to the transistors. In addition, an infrared image-photographing device such as a microscope equipped with a black-and-white charge coupled device camera (CCD camera) and a microprocessor such as a computer are used for extracting the infrared images of the transistors.

In the second embodiment of the invention, the integrated circuit is a radio frequency integrated circuit.

In the third embodiment of the invention, the transistors are heterojunction bipolar transistors (HBT).

According to another aspect of the invention, the method for detecting defectives in an integrated circuit can also be used to perform debugging at the design level of the radio frequency integrated circuit. That is, the foregoing step of applying a bias is replaced by applying a radio frequency signal so that each normal component can radiate infrared light, and then the foregoing inspection device is utilized to track the signal transmission of the radio frequency signal in a complicated circuit.

The advantages of the invention are fast speed, full automation and high accuracy in inspection.

### BRIEF DESCRIPTION OF THE DRAWINGS

FIG. 1 is a schematic diagram showing the configuration of an inspection device used to perform the method for detecting defectives in an integrated circuit according to the present invention.

FIG. 2 is a flow chart showing the steps of the method for detecting defectives in an integrated circuit in an embodiment of the invention.

FIG. 3A is a schematic diagram showing an image of an integrated circuit on a wafer in an embodiment of the invention, wherein the image is extracted by a computer through a microscope equipped with a charge coupled device camera.

FIG. 3B is a schematic diagram showing an image of another integrated circuit on a wafer in an embodiment of the invention, wherein the image is extracted by a computer through a microscope equipped with a charge coupled device camera.

### DESCRIPTION OF THE PREFERRED EMBODIMENTS

As mentioned above, the radio frequency power amplifier (RFPA) in a handset is configured by several tens of transistors in parallel to form a large transistor cell array. These transistors mostly include silicon bipolar transistors, gallium arsenide metal semiconductor field effect transistors (MESFET) and heterojunction bipolar transistors (HBT). As to the heterojunction bipolar transistor, when it is conducting electricity, a phenomenon of radiative recombination will occur in its base region, which means that an infrared light will be emitted. Therefore, the invention utilizes an infrared image display device to inspect an integrated circuit so as to search for the defectives in the integrated circuit.

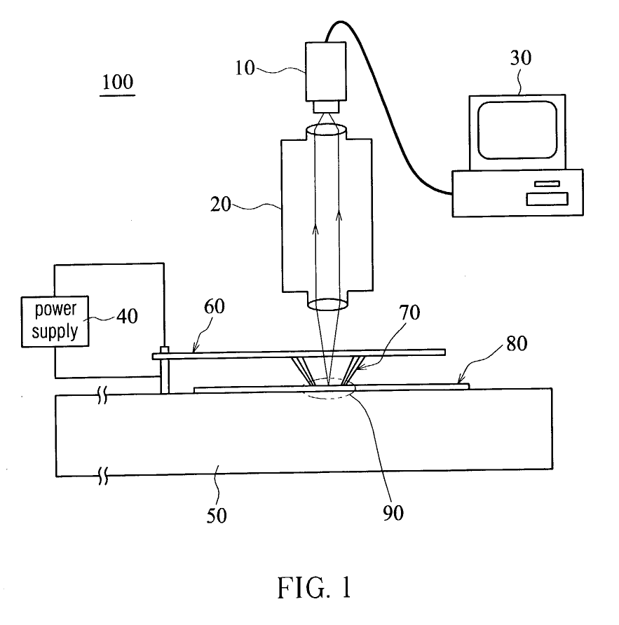

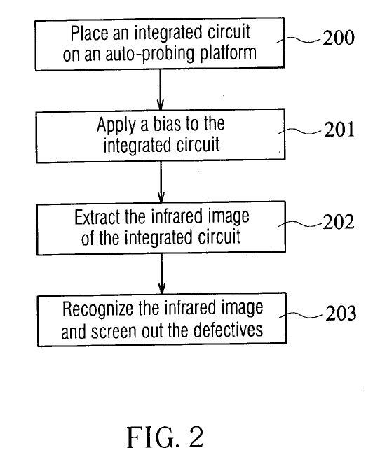

FIG. 1 is a schematic diagram showing the configuration of an inspection device used to perform the method for detecting defectives in an integrated circuit according to the present invention. As shown in FIG. 1, the inspection device 100 used to perform the method for detecting defectives in an integrated circuit includes a charge coupled device camera 10, a microscope 20, a microprocessor/computer 30 installed with image recognition software, a power supply 40, and an auto-probing platform 50. A probe-card holder 60 equipped with a probe 70 thereon is installed on the auto-probing platform 50. The relative positions arranged among all the components of the inspection device 100 are shown in FIG. 1. On the other hand, the steps of inspection performed by the integrated circuit inspection device 100 for detecting defectives are shown in the flowchart of FIG. 2, which are described as follows.

First, a wafer 80 with a portion of IC waiting to be tested 90 is placed and fixed on the auto-probing platform 50. Next, through the probe-card holder 60 installed above the wafer 80, the probe 70 touches the portion of IC waiting to be tested 90 and a bias is applied to it through the probe 70 from a power supplier 40. Then, human eyes may directly observe the image of the portion of IC waiting to be tested 90 through the microscope 20 equipped with the charge coupled device camera 10 installed above the wafer 80, or the microprocessor/computer 30 installed with image recognition software may be used to extract image for image display and recognition. When normal transistors are conducting electricity, they will radiate infrared light; conversely, ineffective and/or burnt-out transistors will not. Therefore, if the portion of IC waiting to be tested 90 contains transistors, by utilizing the infrared sensing function of the microscope 20 equipped with the charge coupled device camera 10, the microprocessor/computer 30 installed with image recognition software can distinguish normal transistors from ineffective and/or burnt-out transistors directly and automatically from the extracted image.

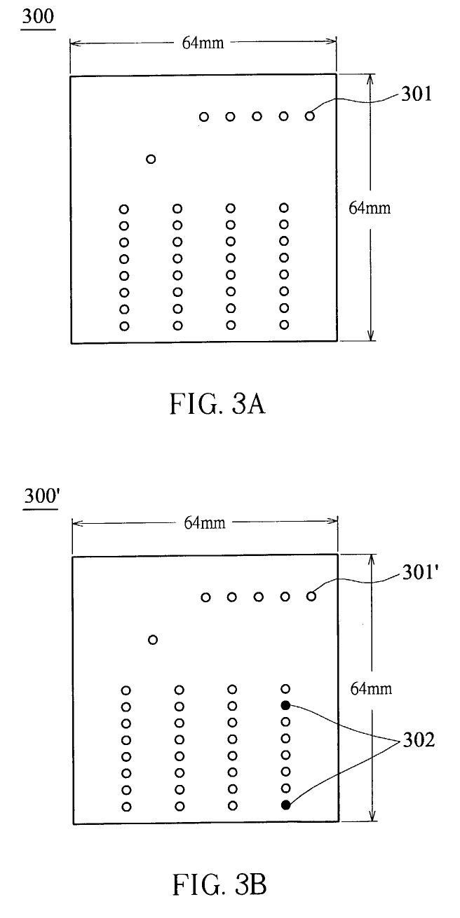

FIG. 3A is a schematic diagram showing an image of radio frequency integrated circuit 300 on a wafer in an embodiment of the invention, wherein the image is extracted by a computer through a microscope equipped with a charge coupled device camera. In FIG. 3A, the size of the radio frequency integrated circuit 300 is about 64×64 mm², and there are totally thirty-eight transistors 301 in parallel on the radio frequency integrated circuit 300. It can be viewed from the extracted image that all the transistors 301 appear to be shinning, which means that all the transistors are normal. FIG. 3B is a schematic diagram showing an image 300′ of another integrated circuit that has the same size as the radio frequency integrated circuit 300 has on a wafer in an embodiment of the invention, wherein the image is extracted by a computer through a microscope equipped with a charge coupled device camera. It can be viewed from the extracted image that all transistors 301′ are shinning except two transistors 302, which means that the two transistors 302 are either ineffective or burnt out.

It should be noted that the above-mentioned probe 70 can also be applied with a direct-current electrical probing test on the portion of IC waiting to be tested 90 in addition to providing a bias on the portion of IC waiting to be tested 90. Also, because the wafer 80 is placed on the auto-probing platform 50, the test of wafer 80 can be completed rapidly due to the movement made by the platform 50. In other words, the method of the invention for detecting defectives in an integrated circuit has the advantages of fast speed, full automation and high accuracy in inspection. Moreover, in another embodiment of the invention, the method for detecting defectives in an integrated circuit can also be used to perform debugging at the design level of the radio frequency integrated circuit. That is, the foregoing step of applying a bias can be replaced by applying a radio frequency signal so that each normal component can radiate infrared light, and then the foregoing inspection device is utilized to track the signal transmission of the radio frequency signal in a complicated circuit.

The invention has been explained in detail through the above embodiments. The embodiments are only intended to illustrate the invention; they do not; however, to limit the invention to the specific embodiments. Accordingly, various modifications and changes can be made without departing from the spirit and scope of the invention as described in the appended claims.

What is claimed is:

1. A method for detecting defectives in an integrated circuit, wherein the integrated circuit is composed of a plurality of transistors in parallel on a wafer, comprising the following two steps:
applying a bias to the transistors; and
extracting infrared images of the transistors.

2. The method for detecting defectives in an integrated circuit as claimed in claim 1, wherein before the bias is applied to the transistors, the wafer is placed on an auto-probing platform equipped with a probe clamp used for holding at least one probe.

3. The method for detecting defectives in an integrated circuit as claimed in claim 2, wherein at least one probe is used for conducting in direct current from a power supply so as to apply the bias to the transistors.

4. The method for detecting defectives in an integrated circuit as claimed in claim 1, wherein the extracting of the infrared images of the transistors are performed by an infrared image-photographing device and a microprocessor.

5. The method for detecting defectives in an integrated circuit as claimed in claim 4, wherein the infrared image-photographing device is a microscope equipped with a black-and-white charge coupled device camera (CCD camera).

6. The method for detecting defectives in an integrated circuit as claimed in claim 4, wherein the microprocessor is a computer.

7. The method for detecting defectives in an integrated circuit as claimed in claim 1, wherein the integrated circuit is a radio frequency integrated circuit.

8. The method for detecting defectives in an integrated circuit as claimed in claim 1, wherein the transistors are heterojunction bipolar transistors (HBT).
